(19) United States
(12) Patent Application Publication
(10) Pub. No.: US 2026/0005138 A1
(43) Pub. Date: Jan. 1, 2026

(54) PACKAGE STRUCTURE AND METHOD OF FORMING THE SAME

(71) Applicant: United Microelectronics Corp., Hsinchu (TW)

(72) Inventors: Yu-Jie Lin, Taichung City (TW); Yi-Feng Hsu, Hsinchu City (TW); Kai-Kuang Ho, Hsinchu City (TW)

(73) Assignee: United Microelectronics Corp., Hsinchu (TW)

(21) Appl. No.: 18/780,541

(22) Filed: Jul. 23, 2024

(30) Foreign Application Priority Data
Jun. 28, 2024 (TW) 113124193

(51) Int. Cl. H01L 23/528; H01L 21/48; H01L 23/00; H01L 23/31; H01L 23/49; H01L 23/532; H01L 25/00; H01L 25/10

(52) U.S. Cl. CPC H01L 23/528; H01L 21/4889; H01L 23/3107; H01L 23/49; H01L 23/53295; H01L 24/20; H01L 25/105; H01L 25/50; H01L 2224/211; H01L 2225/1041

(57) ABSTRACT

Disclosed is a package structure, including: a substrate; a first dielectric layer on the substrate; a second dielectric layer on the first dielectric layer; a multilayer wiring layer in the first dielectric layer and the second dielectric layer; an I/O pad in the first dielectric layer, and a portion of a top surface of the I/O pad is covered by the second dielectric layer; a probe pad in the first dielectric layer and the second dielectric layer, wherein a top surface of the probe pad is higher than the top surface of the I/O pad, and is coplanar with a top surface of the second dielectric layer, and the top surface of the I/O pad is coplanar with a top surface of the first dielectric layer; and an I/O opening is disposed in the second dielectric layer to expose the I/O pad.

### CROSS-REFERENCE TO RELATED APPLICATION

This application claims the priority benefit of Taiwan application serial no. 113124193, filed on Jun. 28, 2024. The entirety of the above-mentioned patent application is hereby incorporated by reference herein and made a part of this specification.

### BACKGROUND

### Technical Field

The present disclosure relates to a semiconductor technology, and in particular, to a packaging structure and a method of forming the same.

### Description of Related Art

In the current semiconductor package structure, a probe pad and an I/O pad are generally placed on the same plane; the probe is first inserted into the probe pad, and chip probe testing (CP testing) is carried out on the wafer. Thereafter, the I/O pad is opened and conducted according to the subsequent package type.

However, in the current technology, the chip is transferred from a semiconductor foundry to a packaging factory for subsequent wire bonding process after the I/O pad is opened. During the transferring process, the surface of the I/O pad is often oxidized as the time elapsed, which causes problems such as wiring failure, or requires further processing to remove the oxide from the surface of the I/O pad to facilitate subsequent wiring, which increases the loading of process and electrical instability.

### SUMMARY

The present disclosure provides a package structure and a method of forming the same, which may solve the problem of surface oxidation of the I/O pad caused by being exposed for a period of time. In the present disclosure, the I/O pad is covered first, and then opened when forming the I/O connection.

A package structure of the present disclosure includes: a substrate; a first dielectric layer disposed on the substrate; a second dielectric layer disposed on the first dielectric layer; a multilayer wiring layer disposed in the first dielectric layer and the second dielectric layer; an I/O pad disposed in the first dielectric layer, and a portion of a top surface of the I/O pad is covered by the second dielectric layer; a probe pad disposed in the first dielectric layer and the second dielectric layer, wherein a top surface of the probe pad is higher than the top surface of the I/O pad, and is coplanar with a top surface of the second dielectric layer, and the top surface of the I/O pad is coplanar with a top surface of the first dielectric layer; and an I/O opening disposed in the second dielectric layer to expose the I/O pad, and the I/O opening is surrounded by the second dielectric layer on the I/O pad.

In an embodiment of the package structure of the present disclosure, the second dielectric layer includes SiCN or TEOS.

In an embodiment of the package structure of the present disclosure, the thickness of the second dielectric layer is 70 angstroms (Å) to 140 angstroms (Å).

In an embodiment of the package structure of the present disclosure, the package structure further includes: an upper die electrically connected to the multilayer wiring layer through an upper wiring layer.

In an embodiment of the package structure of the present disclosure, the package structure further includes an insulating layer located on the second dielectric layer and the probe pad.

In an embodiment of the package structure of the present disclosure, the I/O opening is disposed in the insulating layer.

Another package structure of the present disclosure includes: a substrate; a first dielectric layer disposed on the substrate; a second dielectric layer disposed on the first dielectric layer; a multilayer wiring layer disposed in the first dielectric layer and the second dielectric layer; an I/O pad disposed in the first dielectric layer, and a top surface of the first dielectric layer on the I/O pad is covered by the second dielectric layer; a probe pad disposed in the first dielectric layer and the second dielectric layer, wherein a top surface of the probe pad is higher than the top surface of the I/O pad, and is coplanar with a top surface of the second dielectric layer, and the top surface of the I/O pad is disposed below the top surface of the first dielectric layer; and an I/O opening disposed in the first dielectric layer and the second dielectric layer to expose the I/O pad, and the I/O opening is surrounded by the first dielectric layer and the second dielectric layer on the I/O pad.

In another embodiment of the package structure of the present disclosure, the second dielectric layer includes SiCN or TEOS.

In another embodiment of the package structure of the present disclosure, the thickness of the second dielectric layer is 70 Å to 140 Å.

In another embodiment of the package structure of the present disclosure, the package structure further includes: an upper die electrically connected to the multilayer wiring layer through an upper wiring layer.

In an embodiment of the package structure of the present disclosure, the package structure further includes an insulating layer located on the second dielectric layer and the probe pad.

In another embodiment of the package structure of the present disclosure, the I/O opening is disposed in the insulating layer.

The method for forming a package structure of the present disclosure includes: providing a substrate; forming a multilayer wiring layer, a first dielectric layer and a second dielectric layer on the substrate, wherein the multilayer wiring layer is disposed in the first dielectric layer and the second dielectric layer, and the second dielectric layer is disposed on the first dielectric layer; forming an I/O pad in the first dielectric layer; forming a probe pad in the first dielectric layer and the second dielectric layer, wherein a top surface of the probe pad is higher than a top surface of the I/O pad and is coplanar with a top surface of the second dielectric layer; and forming an I/O opening to expose the I/O pad, and the I/O opening is surrounded by the second dielectric layer on the I/O pad.

In an embodiment of the method for forming the package structure of the present disclosure, the second dielectric layer includes SiCN or TEOS.

In an embodiment of the method for forming the package structure of the present disclosure, the thickness of the second dielectric layer is 70 Å to 140 Å.

In an embodiment of the method for forming the package structure of the present disclosure, the top surface of the I/O pad is coplanar with the top surface of the first dielectric layer, and a portion of the top surface of the I/O pad is covered by the second dielectric layer; alternatively, the top surface of the I/O pad is located below the top surface of the first dielectric layer, and the top surface of the first dielectric layer on the I/O pad is covered by a second dielectric layer.

In an embodiment of the method for forming the package structure of the present disclosure, the method further includes: providing an upper die which is electrically connected to the multilayer wiring layer through an upper wiring layer; forming an insulating layer on the second dielectric layer and the probe pad; and forming the I/O opening in the insulating layer.

In an embodiment of the method for forming the package structure of the present disclosure, the step of exposing the I/O pad is performed before forming the insulating layer or after forming the insulating layer.

In an embodiment of the method for forming the package structure of the present disclosure, the step of exposing the I/O pad includes a general wire bonding process, sputtering bombardment, or laser etching.

In an embodiment of the method for forming the package structure of the present disclosure, the step of forming the insulating layer includes filling a molding material or an oxide material.

Based on the above, in the conventional technology, the top surface of the I/O pad, which is oxidized after being exposed for a period time, is covered by a second dielectric layer in an embodiment of the present disclosure. The second dielectric layer isolates the top surface of the I/O pad from being in contact with the air, thereby preventing the top surface of the I/O pad from being oxidized, so that subsequent I/O connection failure will not occur due to no oxidation of the top surface of the I/O pad, thus maintaining electrical stability.

In addition, the method of directly punching through the second dielectric layer using a general wire bonding process makes it possible to omit the step of removing the oxide from the surface of the I/O pad in the conventional technology.

Furthermore, in the conventional technology, the top surface of the I/O pad, which is oxidized after being exposed for a period time, is covered by a first dielectric layer and a second dielectric layer in another embodiment of the present disclosure. The first dielectric layer and the second dielectric layer isolate the top surface of the I/O pad from being in contact with the air, thereby preventing the top surface of the I/O pad from being oxidized, so that subsequent I/O connection failure will not occur due to no oxidation of the top surface of the I/O pad, thus maintaining electrical stability.

### BRIEF DESCRIPTION OF THE DRAWINGS

FIG. 1A to FIG. 1E are schematic cross-sectional views of a package structure and a method for forming the same according to the first embodiment of the present disclosure.

FIG. 2A to FIG. 2F are schematic cross-sectional views of a package structure and a method for forming the same according to the second embodiment of the present disclosure.

### DESCRIPTION OF THE EMBODIMENTS

The embodiments are described in detail below with reference to the accompanying drawings, but the embodiments are not intended to limit the scope of the present disclosure. In addition, for the purpose of easy understanding, the same components in the following description will be denoted by the same reference symbols.

The terms mentioned in the text, such as “comprising”, “including” and “having” are all open-ended terms, i.e., meaning “including but not limited to”.

When using terms such as “first” or “second” to describe a device, it is only used to distinguish these devices from each other, and does not limit the order or importance of these devices. Therefore, in some cases, the first device can also be called the second device, and the second device can also be called the first device, and this does not deviate from the scope of the present disclosure.

In addition, the directional terms mentioned in the text, such as “up”, “down”, etc., are only used to refer to the direction of the drawings, and are not used to limit the present disclosure. Therefore, it should be noted that “on” can be used interchangeably with “under”, and when an element such as a layer or film is placed “on” another element, the element can be directly placed on the other element, or there may be an intermediate element disposed therebetween. On the other hand, when an element is described as being placed “directly” on another element, there is no intermediate element between the two.

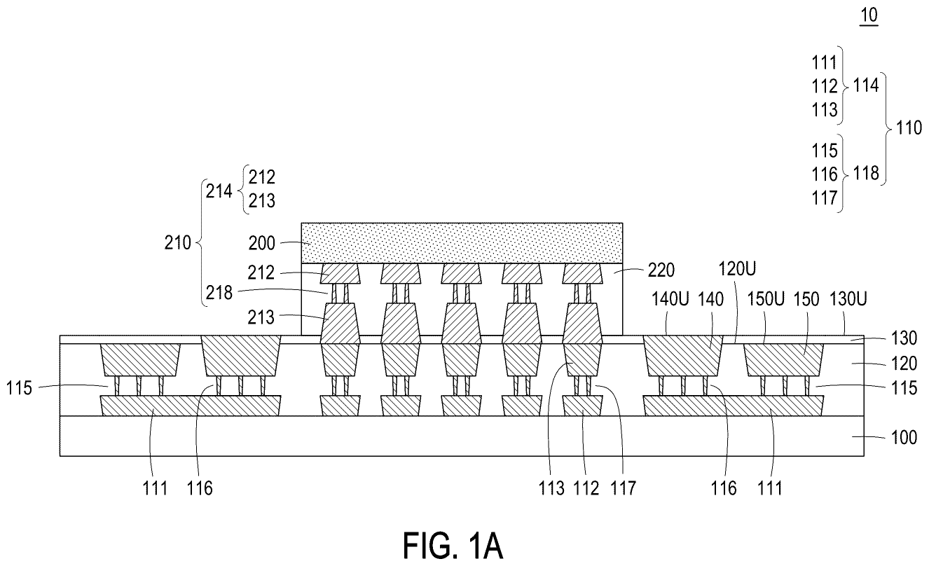

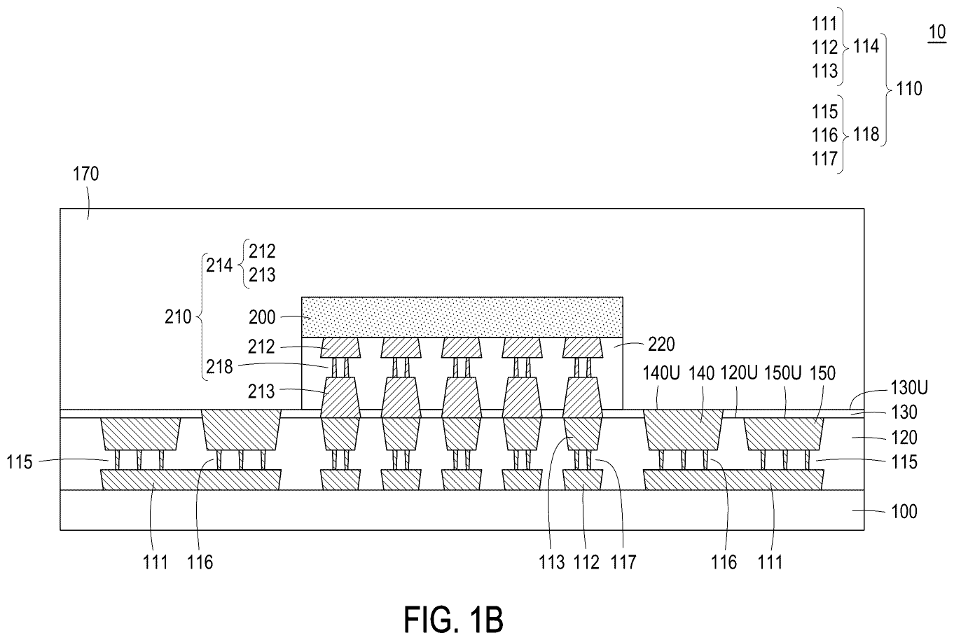

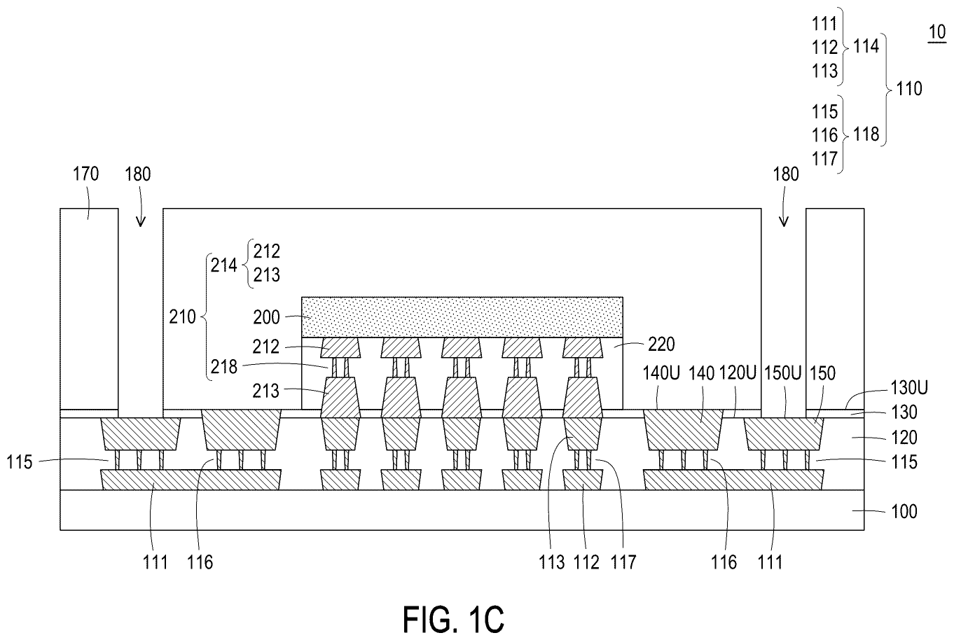

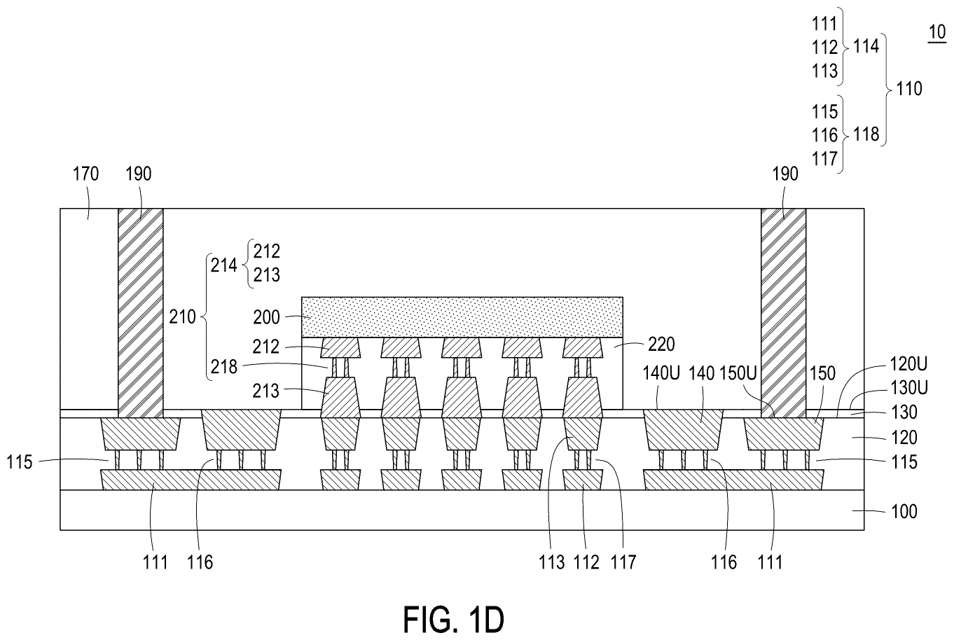

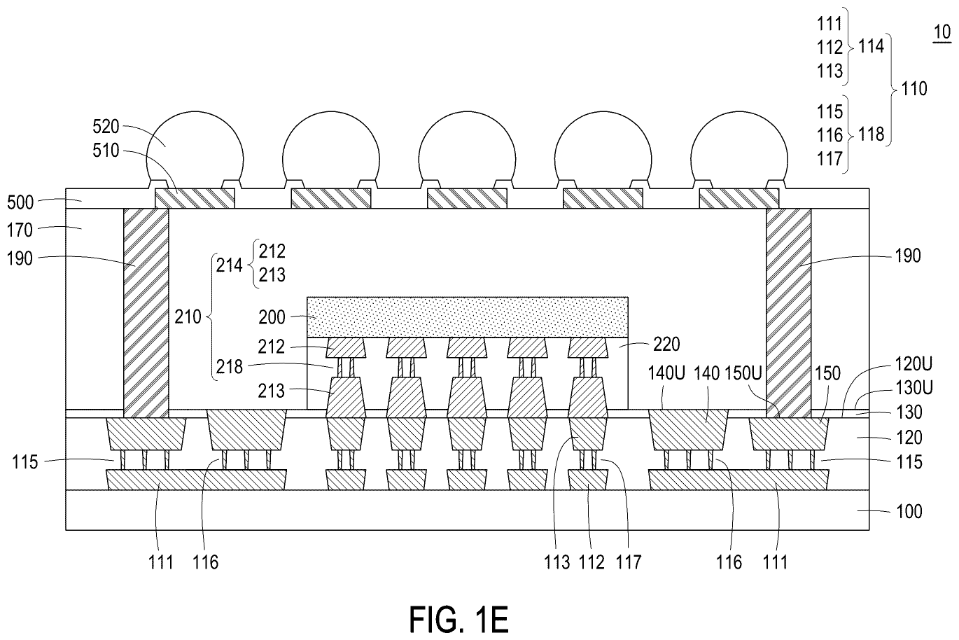

FIG. 1A to FIG. 1E are schematic cross-sectional views of a package structure and a method for forming the same according to the first embodiment of the present disclosure.

Please refer to the package structure 10 shown in FIG. 1A.

First, a substrate 100 is provided. The substrate 100 may include at least one elemental semiconductor, such as silicon or germanium with a single crystal, polycrystalline or amorphous structure; the substrate 100 may also include a compound semiconductor, such as silicon carbide, gallium arsenide, gallium phosphide, indium phosphide, indium arsenide; or the substrate 100 may also include alloy semiconductors, such as silicon germanium (SiGe), gallium arsenide phosphide (GaAsP); or the substrate 100 may also include a combination of the above. The substrate 100 may also include a multilayer semiconductor, a semiconductor on insulator (SOI) (e.g., silicon on insulator or germanium on insulator), or a combination thereof.

In this embodiment, the substrate 100 may be a silicon substrate, but the disclosure is not limited thereto. Furthermore, the substrate 100 may include one or a plurality of bottom dies (not shown).

Next, as shown in FIG. 1A, a multilayer wiring layer 110, a first dielectric layer 120 and a second dielectric layer 130 may be formed on the substrate 100, wherein the multilayer wiring layer 110 is disposed between the first dielectric layer 120 and the second dielectric layer 130, and the second dielectric layer 130 is disposed on the first dielectric layer 120.

As shown in FIG. 1A, the I/O pad 150 is formed in the first dielectric layer 120, and the top surface 150U of the I/O pad 150 is covered by the second dielectric layer 130; and, the probe pad 140 is formed in the first dielectric layer 120 and the second dielectric layer 130, wherein the top surface 140U of the probe pad 140 is higher than the top surface 150U of the I/O pad 150, and the top surface 140U of the probe pad 140 is coplanar with the top surface 130U of the second dielectric layer 130; and the top surface 150U of the I/O pad 150 is coplanar with the top surface 120U of the first dielectric layer 120. That is, the I/O pad 150 is covered by the second dielectric layer 130, but the probe pad 140 is not covered by the second dielectric layer 130.

In this way, in the conventional technology, the top surface 150U of the I/O pad 150 is covered by the second dielectric layer 130 in the present disclosure. The second dielectric layer 130 isolates the top surface 150U of the I/O pad 150 from being in contact with the air, thereby preventing the top surface 150U of the I/O pad 150 from being oxidized, so that the subsequent I/O connection 190 failure will not occur due to no oxidation of the top surface 150U of the I/O pad 150, thus maintaining electrical stability.

The first dielectric layer 120 may include various suitable dielectric layer materials, such as nitride, oxide, silicon oxynitride, etc., wherein the nitride may include silicon nitride, and the oxide may include silicon oxide, phosphosilicate glass (PSG), boron-doped phosphosilicate glass (BPSG), fluorine-doped silicate glass (FSG), etc., and the first dielectric layer 120 may be formed on the substrate 100 by coating or deposition.

The multilayer wiring layer 110 may be formed by various conventional methods and conductive materials, such as copper, aluminum, tungsten and other metals. Various patterning methods are used to form the metal layer 114, a through-plug 118 and the other structures in the first dielectric layer 120. As shown in FIG. 1A, but the disclosure is not limited thereto, the metal layer 114 may include metal layers 111/112 with various sizes located close to the substrate 100 and located in the first dielectric layer 120, as well as the metal layer 113 located far away from the substrate 100 and located in the first dielectric layer 120 and the second dielectric layer 130; wherein the through-plug 118 may include a through-plug 115 connecting the metal layer 111 and the I/O pad 150, a through-plug 116 connecting the metal layer 111 and the probe pad 140, and a through-plug 117 connecting the metal layer 112 and the metal layer 113.

The second dielectric layer 130 may include various suitable dielectric layer materials, such as nitride, oxide, silicon oxynitride, etc., and may be formed on the first dielectric layer 120 and the I/O pad 150 by using deposition, photolithography and etching, etc. According to some embodiments, the second dielectric layer 130 may include SiCN or TEOS. The second dielectric layer 130 may include various suitable thicknesses, e.g., approximately 70 Å to 140 Å.

The probe pad 140 and the I/O pad 150 may be formed by deposition and photolithography and etching, and the materials thereof may include copper (Cu), aluminum (Al), titanium (Ti), tungsten (W), gold (Au), nickel (Ni) and other conductive materials.

Please continue to refer to FIG. 1A. An upper substrate 200 may be provided, which may include an upper die (not shown) and be electrically connected to the multilayer wiring layer 110 through an upper wiring layer 210 formed in the upper dielectric layer 220.

One or a plurality of bottom dies in the substrate 100 and the upper dies in the upper substrate 200 may individually include logic die, memory die, input-output die, passive devices, or the like or a combination of the above. The logic die may include a central processing unit (CPU) die, a graphic processing unit (GPU) die, a mobile application die, a micro control unit (MCU) die, a base band (BB) die, an application processor (AP) die, etc.; the memory die may include a static random access memory (SRAM) die, a dynamic random access memory (DRAM) die, etc.; passive devices may include a capacitor die, an inductor die, a resistor die or the like, or may include a combination of passive devices.

Moreover, the upper wiring layer 210 may be formed of various conventional methods and conductive materials, such as copper, aluminum, tungsten and other metals, and may include an upper metal layer 214 and an upper through-plug 218. As shown in FIG. 1A, but the disclosure is not limited thereto, the upper metal layer 214 may include an upper metal layer 213 electrically connected to the metal layer 113, and an upper metal layer 212 close to the upper substrate 200 and located in the upper dielectric layer 220; and the upper through-plug 218 connects the upper metal layer 212 and the upper metal layer 213.

Referring to FIG. 1B, an insulating layer 170 is formed on the second dielectric layer 130, the probe pad 140 and the upper substrate 200.

The step of forming the insulating layer 170 includes filling molding material or oxide material. The molding materials may include polymers, epoxy, resin, etc.

Referring to FIG. 1C, an I/O opening 180 is formed in the insulating layer 170 by means of photolithography and etching to expose the I/O pad 150, and the I/O opening 180 is surrounded by the second dielectric layer 130 on the I/O pad 150; that is to say, since the above step is performed to remove the insulating layer 170 and the second dielectric layer 130 on the I/O pad 150 to expose the I/O pad 150, the sidewalls of the formed I/O opening 180 are the insulating layer 170 and the second dielectric layer 130. Therefore, the I/O opening 180 near the I/O pad 150 is surrounded by the second dielectric layer 130 on the I/O pad 150.

The above-mentioned step of exposing the I/O pad 150 includes a general wire bonding process, sputtering bombardment, or laser etching.

In addition, in the process of performing a general wire bonding process, before forming the insulating layer 170, the second dielectric layer 130 of SiCN with a thickness of 70 Å to 140 Å is directly punched through to form the I/O opening 180 to expose the I/O pad 150. The method of directly punching through the second dielectric layer 130 using a general wire bonding process makes it possible to omit the step of removing the oxide from the surface of the I/O pad in the conventional technology.

Referring to FIG. 1D, the conductive material is filled in the I/O opening 180 by plating or plating plus sputtering to form the I/O connection 190, for example, the conductive material is filled into the I/O opening 180 by using Ti/Cu sputtering plus Cu plating to form the I/O connection 190.

Therefore, the second dielectric layer 130 on the I/O pad 150 may be directly punched through by performing the inherently subsequent general wire bonding process. In this way, there is no need to perform the step of removing the oxide from the top surface 150U of the I/O pad 150 in the conventional technology.

Next, the package structure shown in FIG. 1D may be subjected to various subsequent packaging processes depending on requirements, such as using ball grid array (BGA) packaging for subsequent processes. As shown in FIG. 1E, a protective layer 500 is formed on the insulating layer 170 and the I/O connection 190, and a conductive pad 510 is formed therein to be electrically connected with the I/O connection 190, etc., and a metal bump 520 is formed on the conductive pad 510, wherein the metal bump 520 may be include one formed of gold (Au), copper (Cu), nickel (Ni), tin (Sn), or alloys thereof.

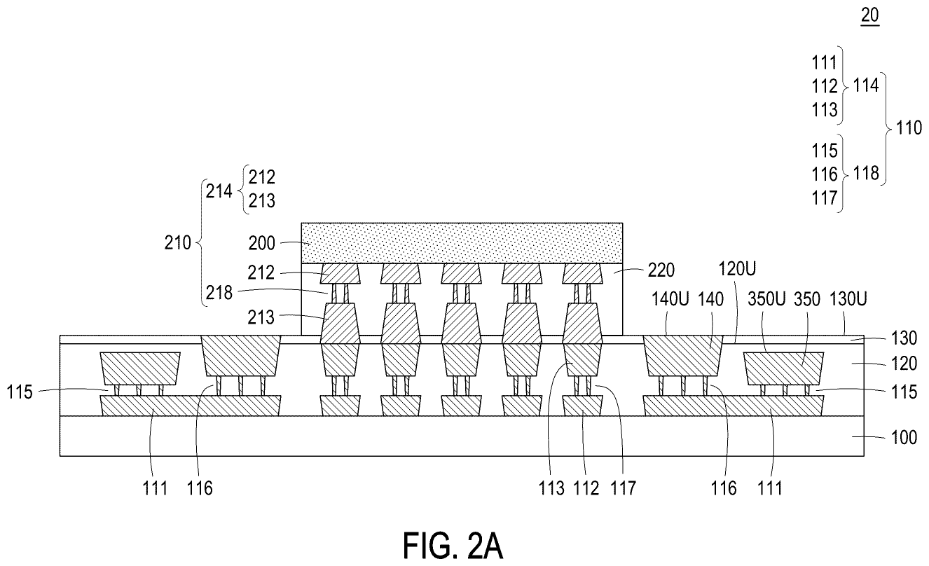

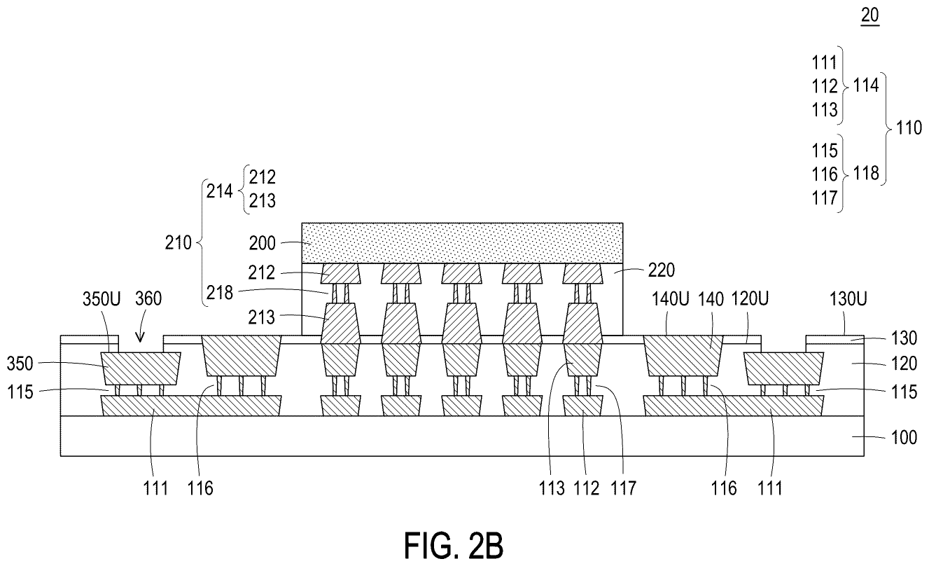

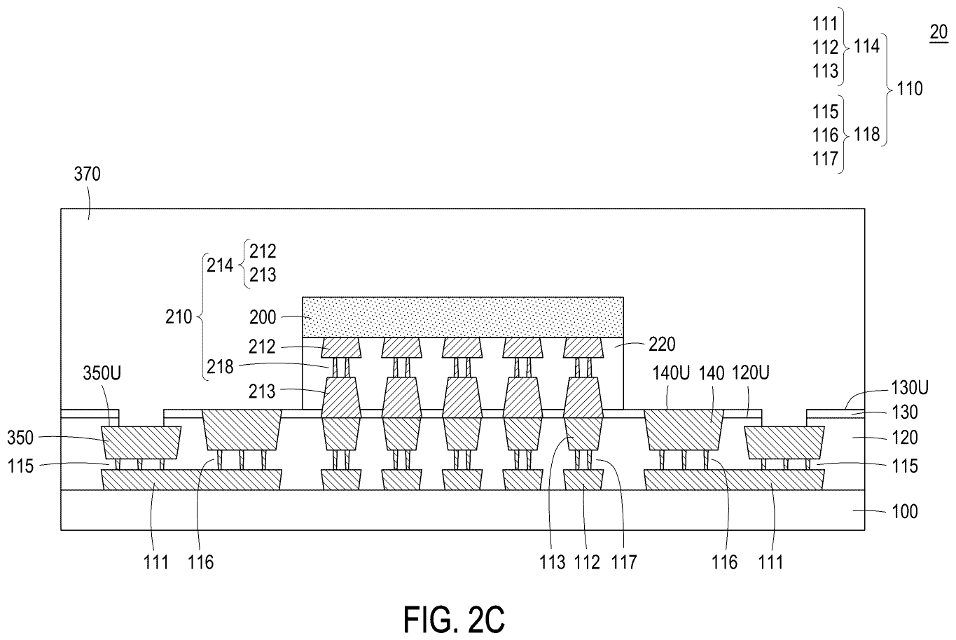

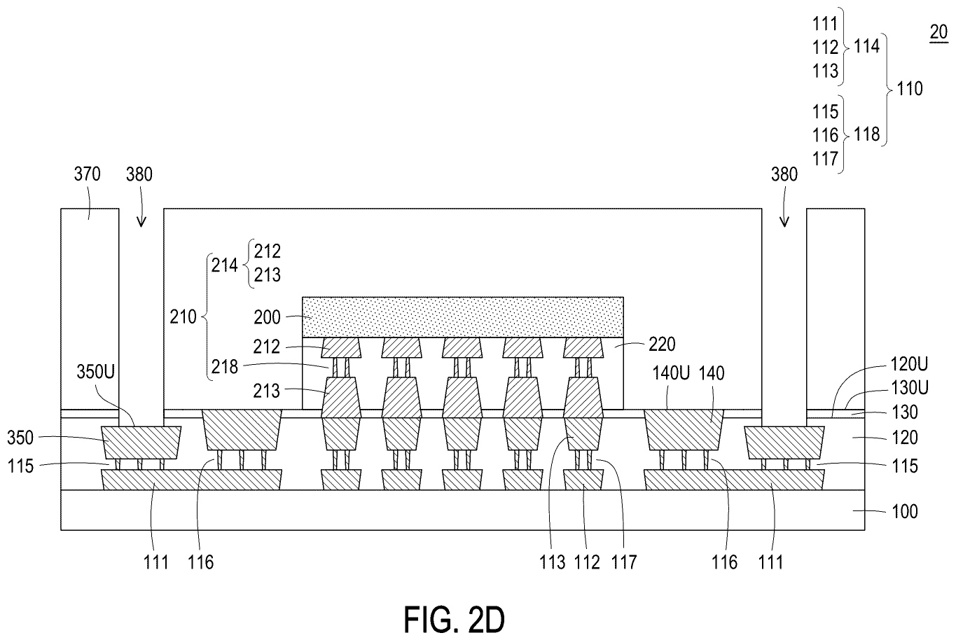

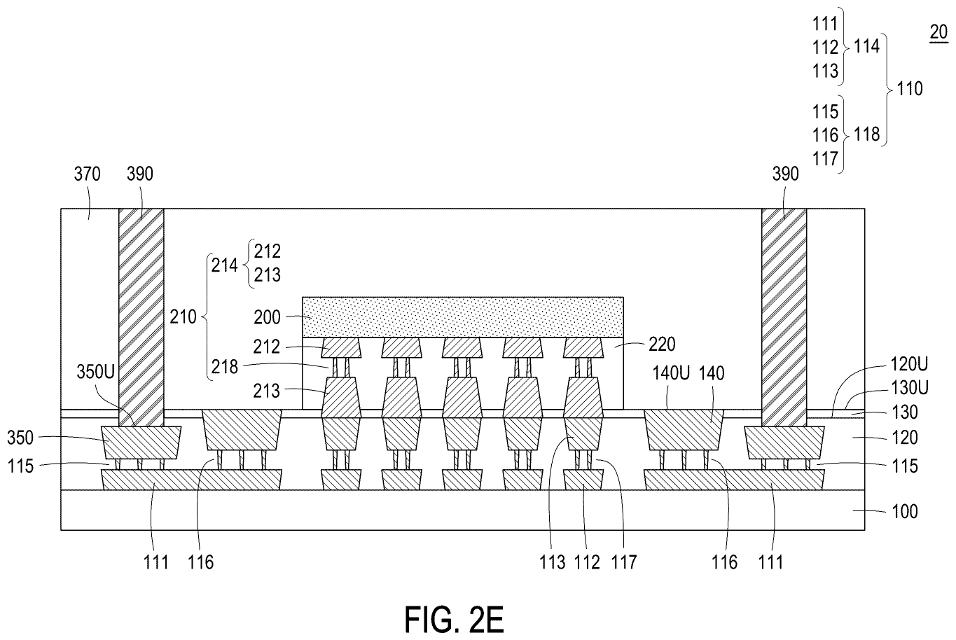

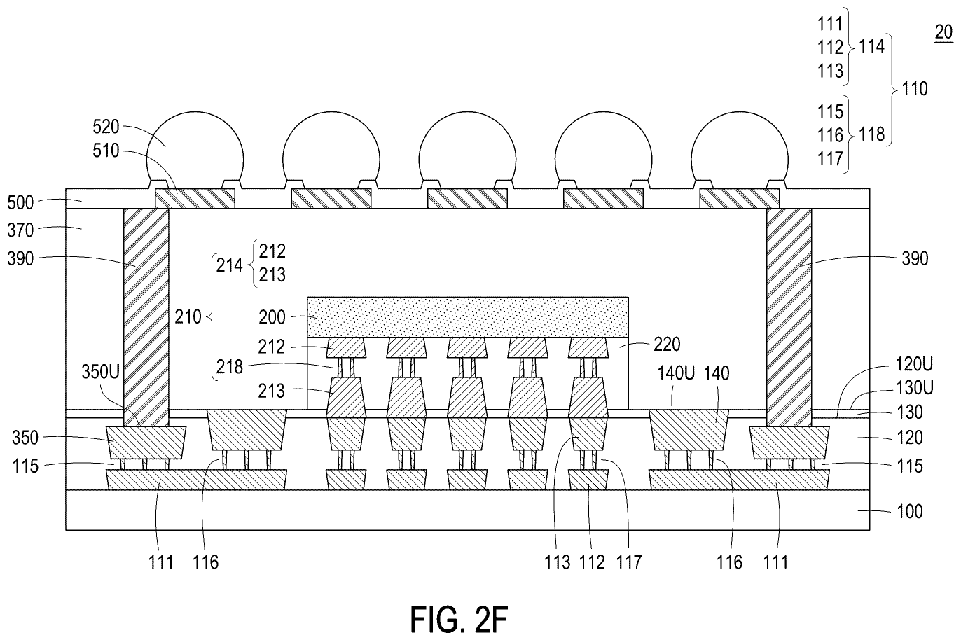

FIG. 2A to FIG. 2F are schematic cross-sectional views of a package structure and a method for forming the same according to the second embodiment of the present disclosure. In this embodiment, the same elements as those in the first embodiment will be denoted by the same reference symbols, and related details will not be described again.

First, please refer to the package structure 20 shown in FIG. 2A. The difference between the package structure 20 and the package structure 10 of FIG. 1A of the first embodiment is that the top surface 350U of the I/O pad 350 is disposed below the top surface 120U of the first dielectric layer 120, and the top surface 120U of the first dielectric layer 120 on the I/O pad 350 is covered by the second dielectric layer 130. Moreover, as shown in FIG. 2D, the I/O opening 380 is disposed in the first dielectric layer 120 and the second dielectric layer 130 to expose the I/O pad 350, and the I/O opening 380 is surrounded by the first dielectric layer 120 and the second dielectric layer 130 on the I/O pad 350.

As a result, the top surface 350U of the I/O pad 350, which is oxidized after being exposed for a period time, is covered by the first dielectric layer 120 and the second dielectric layer 130 in the present disclosure. The first dielectric layer 120 and the second dielectric layer 130 isolate the top surface 350U of the I/O pad 350 from being in contact with the air, thereby preventing the top surface 350U of the I/O pad 350 from being oxidized, so that subsequent I/O connection 390 failure will not occur due to no oxidation of the top surface 350U of the I/O pad 350, thus maintaining electrical stability

The second dielectric layer 130 may include various suitable dielectric layer materials, such as SiCN or TEOS. The second dielectric layer 130 may include various suitable thicknesses, such as 70 Å to 140 Å.

In the first embodiment, the step of exposing the I/O pad 150 is performed after forming the insulating layer 170, as shown in FIG. 1B and FIG. 1C.

However, the step of exposing the I/O pad 350 may also be performed before forming the insulating layer 370, as described later in FIG. 2B and FIG. 2C, and then the I/O opening 380 is formed thereafter as shown in FIG. 2D, thereby forming the I/O connection 390 as shown in FIG. 2E.

Referring to FIG. 2B, the first dielectric layer 120 and the second dielectric layer 130 above the I/O pad 350 are removed by photolithography and etching to form the I/O through hole 360 that exposes the top surface 350U of the I/O pad 350.

The above step of exposing the I/O pad 350 includes sputtering bombardment or laser etching, etc.

In comparison with the first embodiment, the top surface 150U of the I/O pad 150 is coplanar with the top surface 120U of the first dielectric layer 120, as shown in FIG. 1A, therefore, it is only required to consider removing the second dielectric layer 130 from the top surface 150U of the I/O pad 150 to expose the I/O pad 150.

However, in the second embodiment, as shown in FIG. 2A, since the top surface 350U of the I/O pad 350 is located below the top surface 120U of the first dielectric layer 120, different from the first embodiment, it is not only required to consider removing the second dielectric layer 130 on the top surface 350U of the I/O pad 350, but also required to consider removing the first dielectric layer 120 on the top surface 350U of the I/O pad 350. Accordingly, sputtering bombardment or laser etching with higher energy may be used to form the I/O through hole 360 to expose the I/O pad 350.

Referring to FIG. 2C, an insulating layer 370 is formed on the top surface 350U of the I/O pad 350, the second dielectric layer 130, the probe pad 140 and the upper substrate 200.

The step of forming the insulating layer 370 includes filling molding material or oxide material. The molding materials may include polymers, epoxy, resin, etc.

Referring to FIG. 2D, an I/O opening 380 is formed in the insulating layer 370 by means of photolithography and etching to expose the I/O pad 350, and the I/O opening 380 is surrounded by the first dielectric layer 120 and the second dielectric layer 130 on the I/O pad 350. That is to say, the above step is to remove the insulating layer 370 on the I/O pad 350 to expose the I/O pad 350. Before forming the I/O opening 380, since the first dielectric layer 120 and the second dielectric layer 130 on the I/O pad 350 have already been removed through the step of forming the I/O through hole 360, the sidewalls of the formed I/O opening 380 are the insulating layer 370, the first dielectric layer 120 and the second dielectric layer 130. Accordingly, the I/O opening 380 near the I/O pad 350 is surrounded by the first dielectric layer 120 and the second dielectric layer 130 on the I/O pad 350.

Referring to FIG. 2E, the conductive material is filled in the I/O opening 380 to form the I/O connection 390. The conductive material is filled into the I/O opening 380 to form the I/O connection 390 by plating or plating plus sputtering, for example, the conductive material is filled into the I/O opening 380 by using Ti/Cu sputtering plus Cu plating to form the I/O connection 390.

Like the first embodiment, following the package structure shown in FIG. 1D, the package structure may be subjected to various subsequent packaging processes depending on requirements. For example, as shown in FIG. 1E, the package structure in FIG. 2E in the second embodiment may adopt ball grid array (BGA) packaging for subsequent processes. As shown in FIG. 2F, a protective layer 500 is formed on the insulating layer 370 and the I/O connection 390, and a conductive pad 510 is formed therein to be electrically connected with the I/O connection 390, etc., and a metal bump 520 is formed on the conductive pad 510, wherein the metal bump 520 may be include one formed of gold (Au), copper (Cu), nickel (Ni), tin (Sn), or alloys thereof.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the scope to be protected by the present disclosure shall be determined by the scope of the appended claims.

What is claimed is:

1. A package structure, comprising:
a substrate;
a first dielectric layer disposed on the substrate;
a second dielectric layer disposed on the first dielectric layer;
a multilayer wiring layer disposed in the first dielectric layer and the second dielectric layer;
an I/O pad disposed in the first dielectric layer, and a portion of a top surface of the I/O pad being covered by the second dielectric layer;
a probe pad disposed in the first dielectric layer and the second dielectric layer, wherein
a top surface of the probe pad is higher than the top surface of the I/O pad, and is coplanar with a top surface of the second dielectric layer, and
the top surface of the I/O pad is coplanar with a top surface of the first dielectric layer; and
an I/O opening disposed in the second dielectric layer to expose the I/O pad, and the I/O opening being surrounded by the second dielectric layer on the I/O pad.

2. The package structure according to claim 1, wherein the second dielectric layer comprises SiCN or TEOS.

3. The package structure according to claim 1, wherein a thickness of the second dielectric layer is 70 angstroms (Å) to 140 angstroms (Å).

4. The package structure according claim 1, further comprising:
an upper die electrically connected to the multilayer wiring layer through an upper wiring layer.

5. The package structure according to claim 4, further comprising an insulating layer disposed on the second dielectric layer and the probe pad.

6. The package structure according to claim 5, wherein the I/O opening is disposed in the insulating layer.

7. A package structure, comprising:
a substrate;
a first dielectric layer disposed on the substrate;
a second dielectric layer disposed on the first dielectric layer;
a multilayer wiring layer disposed in the first dielectric layer and the second dielectric layer;
an I/O pad disposed in the first dielectric layer, and a top surface of the first dielectric layer on the I/O pad being covered by the second dielectric layer;
a probe pad disposed in the first dielectric layer and the second dielectric layer, wherein
a top surface of the probe pad is higher than a top surface of the I/O pad, and is coplanar with a top surface of the second dielectric layer, and
the top surface of the I/O pad is disposed below the top surface of the first dielectric layer; and
an I/O opening disposed in the first dielectric layer and the second dielectric layer to expose the I/O pad, and the I/O opening being surrounded by the first dielectric layer and the second dielectric layer on the I/O pad.

8. The package structure according to claim 7, wherein the second dielectric layer comprises SiCN or TEOS.

9. The package structure according to claim 7, wherein a thickness of the second dielectric layer is 70 Å to 140 Å.

10. The package structure according to claim 7, further comprising:
an upper die electrically connected to the multilayer wiring layer through an upper wiring layer.

11. The package structure according to claim 10, further comprising an insulating layer disposed on the second dielectric layer and the probe pad.

12. The package structure according to claim 11, wherein the I/O opening is disposed in the insulating layer.

13. A method for forming a package structure, comprising:
providing a substrate;
forming a multilayer wiring layer, a first dielectric layer and a second dielectric layer on the substrate, wherein the multilayer wiring layer is disposed in the first dielectric layer and the second dielectric layer, and the second dielectric layer is disposed on the first dielectric layer;
forming an I/O pad in the first dielectric layer;
forming a probe pad in the first dielectric layer and the second dielectric layer, wherein
a top surface of the probe pad is higher than a top surface of the I/O pad and is coplanar with a top surface of the second dielectric layer; and
forming an I/O opening to expose the I/O pad, and the I/O opening being surrounded by the second dielectric layer on the I/O pad.

14. The method for forming the package structure according to claim 13, wherein the second dielectric layer comprises SiCN or TEOS.

15. The method for forming the package structure according to claim 13, wherein a thickness of the second dielectric layer is 70 Å to 140 Å.

16. The method for forming the package structure according to claim 13, wherein the top surface of the I/O pad is coplanar with a top surface of the first dielectric layer, and a portion of the top surface of the I/O pad is covered by the second dielectric layer; alternatively, the top surface of the I/O pad is located below the top surface of the first dielectric layer, and the top surface of the first dielectric layer on the I/O pad is covered by the second dielectric layer.

17. The method for forming the package structure according to claim 13, further comprising:
providing an upper die which is electrically connected to the multilayer wiring layer through an upper wiring layer;
forming an insulating layer on the second dielectric layer and the probe pad; and
forming the I/O opening in the insulating layer.

18. The method for forming the package structure according to claim 17, wherein the step of exposing the I/O pad is performed before forming the insulating layer or after forming the insulating layer.

19. The method for forming the package structure according to claim 13, wherein the step of exposing the I/O pad comprises a general wire bonding process, sputtering bombardment, or laser etching.

20. The method for forming the package structure according to claim 17, wherein the step of forming the insulating layer comprises filling a molding material or an oxide material.
